(19) United States
(12) Patent Application Publication
(10) Pub. No.: US 2008/0122040 A1
(43) Pub. Date: May 29, 2008

(54) Varying Pitch Adapter and a Method of Forming a Varying Pitch Adapter

(75) Inventors: Conor Brogan, Belfast (GB); Cormac MacNamara, Belfast (GB); Hugh J. Griffin, Newtownabbey (GB); Robin Wilson, Holywood (GB)

Correspondence Address: PANITCH SCHWARZE BELISARIO & NADEL LLP, ONE COMMERCE SQUARE, 2005 MARKET STREET, SUITE 2200, PHILADELPHIA, PA, 19103, US

(73) Assignee: ICEMOS TECHNOLOGY CORPORATION, Tempe, AZ (US)

(21) Appl. No.: 11/772,104

(22) Filed: Jun. 29, 2007

Related U.S. Application Data
(60) Provisional application No. 60/806,150, filed on Jun. 29, 2006.

(51) Int. Cl. H01L 23/48; H01L 21/44

(52) U.S. Cl. 257/621; 438/667; 257/E23.01; 257/E21.476

(57) ABSTRACT

A varying pitch adapter that converts a first pitch to a second pitch. The adapter comprises a substrate, a plurality of first conductive vias, at least one second conductive via, a first dielectric layer and a second dielectric layer. The substrate has a first main surface and a second main surface. The plurality of first conductive vias extend through the substrate from the first main surface to the second main surface. The second conductive via is disposed in a portion of the first main surface and the second main surface. The second conductive via is coupled to at least one of the plurality of first conductive vias. The first dielectric layer covers at least the portion of the first main surface of the substrate. The second dielectric layer covers at least a portion of the second main surface of the substrate.

### CROSS-REFERENCE TO RELATED APPLICATIONS

This application claims the benefit of U.S. Provisional Application No. 60/806,150 filed Jun. 29, 2006.

### BACKGROUND OF THE INVENTION

Embodiments of the present invention relate to an adapter and a method for manufacturing the adapter, and more particularly, to a varying pitch adapter having a substrate with conductive vias and a method of manufacturing the varying pitch adapter.

Standard integrated circuit (IC) packages typically include pins or pads. For through-hole applications, ICs typically have pins with a “pitch” of about 0.5-0.65 millimeters (mm), where pitch is the spacing between lead-pins on the IC package. Newer surface mount technology has gone to smaller pitch spacing on the order of 0.4-0.5 mm. Depending on the application, some printed circuit boards (PCBs) may require a mix of surface mount and conventional through-hole devices. Likewise, some manufacturers may desire to offer their newer surface mount ICs in multiple pitch spacing.

It is desirable to provide a varying pitch adapter device. It is desirable to provide a varying pitch adapter device formed of a substrate with conductive vias for connecting to an electrical or electronic component having a first pitch in order to provide a second pitch different from the first pitch. It is also desirable to form conductive vias in a semiconductor substrate material to form a varying pitch adapter for electronic components.

### BRIEF SUMMARY OF THE INVENTION

Briefly stated, an embodiment of the present invention comprises a varying pitch adapter that converts a first pitch to a second pitch. The adapter comprises a substrate, a plurality of first conductive vias, at least one second conductive via, a first dielectric layer and a second dielectric layer. The substrate has a first main surface and a second main surface. The plurality of first conductive vias extend through the substrate from the first main surface to the second main surface. The second conductive via is disposed in a portion of the at least one of the first main surface and the second main surface. The at least one of the second conductive via is coupled to at least one of the plurality of first conductive vias. The first dielectric layer covers at least the portion of the first main surface of the substrate. The second dielectric layer covers at least a portion of the second main surface of the substrate.

Another embodiment of the present invention comprises a method of forming a varying pitch adapter that includes providing a substrate having a first main surface and a second main surface opposite the first main surface. A plurality of first trenches are formed through the substrate from the first main surface to the second main surface. At least one second trench is formed adjacent to one of the plurality of first trenches on at least one of the first main surface and the second main surface. The first trenches and the at least one second trench are at least partially filled with a conductive material.

Another embodiment of the present invention comprises a method of forming a varying pitch adapter that includes providing a semiconductor substrate having a first main surface and a second main surface opposite the first main surface. A plurality of first trenches are formed through the substrate from the first main surface to the second main surface by Reactive Ion Etching (RIE). A plurality of second trenches are formed in one of the first and the second main surfaces by RIE. Each of the plurality of second trenches are disposed adjacent to a respective one of the plurality of first trenches. Walls of the plurality of first trenches and walls of the plurality of second trenches are lined with a dielectric material. The plurality of first trenches and the plurality of second trenches are filled with a conductive material in order to create a plurality of conductive vias through the semiconductor substrate. A first dielectric layer is formed on the first main surface of the semiconductor substrate with the dielectric material. A second dielectric layer is formed on the second main surface of the semiconductor substrate with the dielectric material. A portion of each of the plurality of conductive vias are exposed on the first main surface of the semiconductor substrate. A portion of each of the plurality of conductive vias are exposed on the second main surface of the semiconductor substrate.

### BRIEF DESCRIPTION OF THE SEVERAL VIEWS OF THE DRAWINGS

The foregoing summary, as well as the following detailed description of the invention, will be better understood when read in conjunction with the appended drawings. For the purpose of illustrating the invention, there are shown in the drawings embodiments which are presently preferred. It should be understood, however, that the invention is not limited to the precise arrangements and instrumentalities shown. In the drawings:

FIG. 1 is a cross-sectional view of varying pitch that includes a substrate having contacts with a first pitch on a first surface and contacts with a second pitch on a second surface in accordance with a preferred embodiment of the present invention;

FIG. 2 is a top plan view of the varying pitch adapter of FIG. 1;

FIG. 3 is a cross-sectional elevational view of a substrate used to form the varying pitch adapter of FIG. 1;

FIG. 4 is a cross-sectional elevational view of the substrate of FIG. 3 having a plurality of trenches extending through the substrate from the first surface to the second surface;

FIG. 5 is a cross-sectional elevational view of the substrate of FIG. 4 with a plurality of second trenches formed in a portion of the first or second main surface of the substrate;

FIG. 6 is a cross-sectional elevational view of the substrate of FIG. 5 with a dielectric formed on and covering the first and second trenches;

FIG. 7 is a cross-sectional elevational view of the substrate of FIG. 6 with the insulated first and second trenches filled with a conductive material; and

FIG. 8 is a cross-sectional elevational view of the substrate of FIG. 7 with a dielectric formed on and covering the first and second main surfaces of the substrate.

### DETAILED DESCRIPTION OF THE INVENTION

Certain terminology is used in the following description for convenience only and is not limiting. The words “right”, “left”, “lower”, and “upper” designate directions in the drawings to which reference is made. The words “inwardly” and “outwardly” refer to direction toward and away from, respectively, the geometric center of the object described and designated parts thereof. The terminology includes the words above specifically mentioned, derivatives thereof and words of similar import. Additionally, the words “a” and “an,” as used in the claims and in the corresponding portion of the specification, means “at least one.”

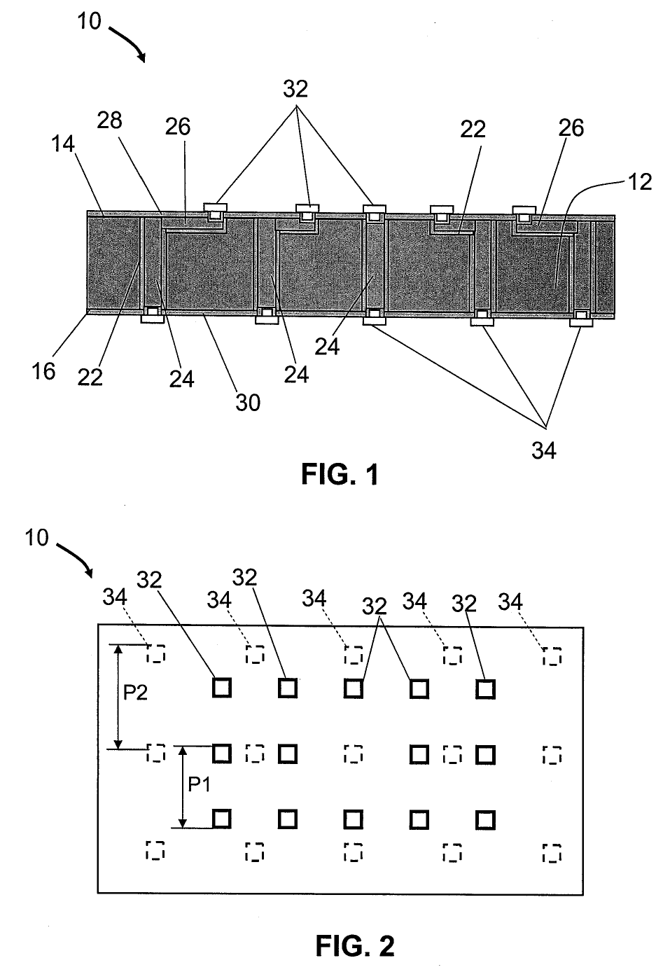

Referring to the drawings in detail, wherein like numeral references indicate like elements throughout, FIG. 1 shows a varying pitch adapter 10 converter in accordance with a preferred embodiment of the present invention. The adapter includes a substrate 12 with a first main surface 14 and a second main surface 16 opposite to the first main surface 14. The substrate 12 includes a plurality of first conductive vias 24 that extend through the substrate 12 from the first main surface 14 to the second main surface 16. The substrate 12 also has a plurality of second conductive vias 26 disposed in a portion of at least one of the first main surface 14 and the second main surface 16 of the substrate 12. The second conductive vias 26 are each coupled to a respective one of the plurality of the first conductive vias 24. A first dielectric layer 28 is formed on and covers at least a portion of the first main surface 14 of the substrate 12. A second dielectric layer 30 is formed on and covers at least a portion of the second main surface 16 of the substrate 12. Alternatively, the second conductive vias 26 may be formed on top of the first or second surface 14, 16 and then covered by the first or second dielectric layer 28, 20, respectively.

The substrate 12 can be formed of silicon (Si), gallium arsenide (GaAs), germanium (Ge), aluminum, copper, sapphire, diamond, silicon carbide (SiC), ceramic and the like. Preferably, the substrate 12 is formed of a semiconductor material such as silicon so that semiconductor fabricating techniques can be used in manufacturing the varying pitch adapter such as wet chemical etching, dry chemical etching, RIE or the like. The substrate 12 is generally uniform in thickness and is generally rectangular in shape. But, the substrate 12 may be any shape depending on the application such as square or circular.

Optionally, the varying pitch adapter 10 also includes a third dielectric layer 22 that surrounds each of the plurality of conductive vias 24, 26 formed in the substrate 12 in order to isolate the conductive vias 24, 26 from the substrate 12 when the substrate is formed of a conductive material such as silicon. The third dielectric layer 22 is interposed between each of the plurality of first conductive vias 24, each of the second conductive vias 26 and the substrate 12.

Preferably, the dielectric layers 22, 28 and 30 are an oxide, such as silicon dioxide (SiO₂). But, the dielectric layers 22, 28, 30 can be made of other dielectric materials such as silicon nitride (SiₓN_{y}) or semi-insulating materials such as polycrystalline silicon (SIPOS) or the like. When the substrate 12 is formed of an inert or insulative material, such as sapphire, the dielectric layers 22, 28, may not be necessary.

The varying pitch adapter 10 includes a plurality of first contact pads 32 disposed on the first main surface 14 separated by a first pitch P1 that are electrically isolated from the substrate 12 and electrically coupled to a respective one of the plurality of conductive vias 24, 26. The varying pitch adapter 10 also includes a plurality of second contact pads 34 on the second main surface 16 separated by a second pitch P2 that are electrically isolated from the substrate 12 and electrically coupled to a respective one of the plurality of conductive vias 24, 26.

FIG. 2 is a top plan view of the varying pitch adapter 10 of FIG. 1 showing the offset or difference between the first pitch P1 and the second pitch P2. Each contact pad 32 on the first main surface 14 is separated by the first pitch P1, such as 0.4 or 0.5 mm, and each contact pad 34 on the second surface 16 is separated by the second pitch P2, such as 0.5 mm-0.65 mm. The plurality of first contact pads 32, 34 are electrically isolated from the substrate 12 by the first and second dielectric layers 28, 30, respectively. Each of the first contact pads 32 are electrically coupled to a respective one of each of the second contact pads 34 by respective conductive vias 24, 26. Thus, the varying pitch adapter 10 provides electrical conductivity from the first main surface 14 with the first pitch P1 to the second main surface 16 with the second pitch P2. Electrical conductivity is facilitated by the plurality of first conductive vias 24 extending through the substrate 12 and the plurality of second conductive vias 26, which are disposed in a portion of one of the first and second main surfaces 14, 16 in order to provide the shift or offset in pitch between the first pitch P1 and the second pitch P2.

The first conductive vias 24 are generally normal with respect to the first and second surfaces 14, 16, as shown in FIG. 1, but the first conductive vias 24 can have any angle with respect to either of the first and second main surfaces 14, 16. The second conductive vias 26 are generally parallel to and formed in or on the first and second main surfaces 14, 16, but the second conductive vias 26 may have any orientation that allows for each second conductive via 26 to be coupled to each respective first conductive via 24 and to provide proper routing between the first pitch P1 and the second pitch P2. The first and second conductive vias 24, 26 provide interconnectivity between the first and second main surfaces 14, 16 of the substrate 12 of the varying pitch adapter 10, wherein the first and second contacts 32, 34 have a first and a second pitch P1, P2, respectively. The first and second pitch P1, P2 allows for a device or component that has leads or contacts with a narrower pitch to be converted to have a broader or narrower pitch, lead or contact that is offset.

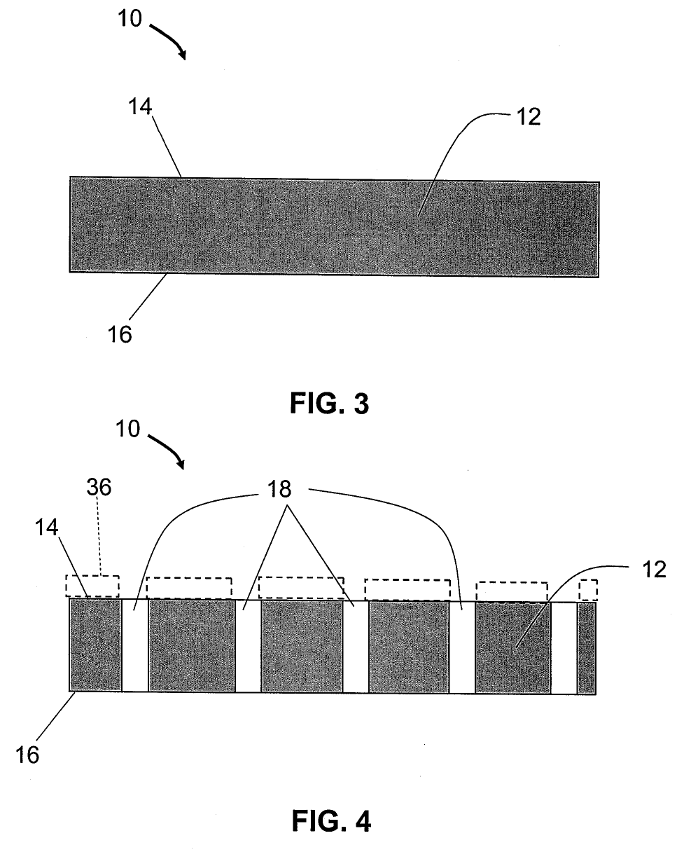

FIGS. 3-7 generally show a method for forming the varying pitch adapter 10 of FIGS. 1-2, in accordance with a preferred embodiment of the present invention.

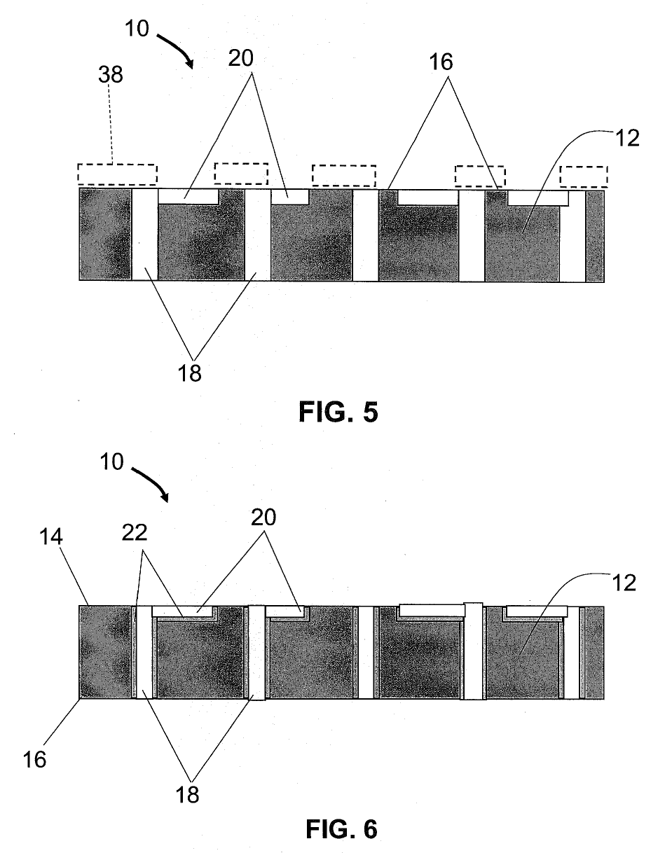

FIG. 3 shows the substrate 12 having first and second main surfaces 14, 16, respectively. A first photomask 36 (phantom in FIG. 4) is formed over at least a portion of the first main surface 14 of the substrate 12. The first photomask 36 is formed using any known photolithography or similar masking technique. FIG. 4 shows that a plurality of first trenches 18 are formed through the substrate 12 from the first main surface 14 to the second main surface 16. After forming the plurality of first trenches 18, the first photomask 36 is removed from the first main surface 14 of the substrate 12. A second photomask 38 (phantom in FIG. 5) is formed over at least a portion of one of the first main surface 14 and the second main surface 16 of the substrate 12, depending on the desired routing of the second conductive vias 26 that will be formed. The second photomask 38 is formed using any known photolithography or similar masking technique. FIG. 5 shows that least one second trench 20 is formed adjacent to one of the plurality of first trenches 18 in at least one of the first and second main surfaces 14, 16, but preferably, a plurality of second trenches 20 are formed in at least one of the first and second main surfaces 14, 16. After forming the at least one second trench, the second photomask 38 from the first main surface 14 or the second main surface 16 of the substrate 12.

The plurality of first trenches 18 can be formed in the substrate 12 by using a variety of techniques, which are chosen according to the material of construction of the substrate 12. For example, for an aluminum substrate, the plurality of first trenches 18 may be formed by using one of mechanical machining, drilling and other similar techniques. When the substrate material is a harder material, such as sapphire, SiC or diamond, more aggressive machining techniques may be required such as laser etching, high pressure water jet etching, slurry etching or mechanical etching. When the substrate 12 is formed of a semiconductor material such as silicon, conventional semiconductor etching may be used. Preferably, the plurality of first trenches 18 and the plurality of second trenches 20 are formed by RIE. The etching process can also be a wet chemical etch, a dry chemical etch, a plasma etch, sputter etching, vapor phase etching or the like.

Prior to forming the first trenches 18, the first main surface 14 may be planarized, polished and/or ground using a process such as chemical mechanical polishing (CMP) or other techniques known in the art. Prior to forming the second trenches 20, the first or second main surface 14, 16 may also be planarized, polished or ground.

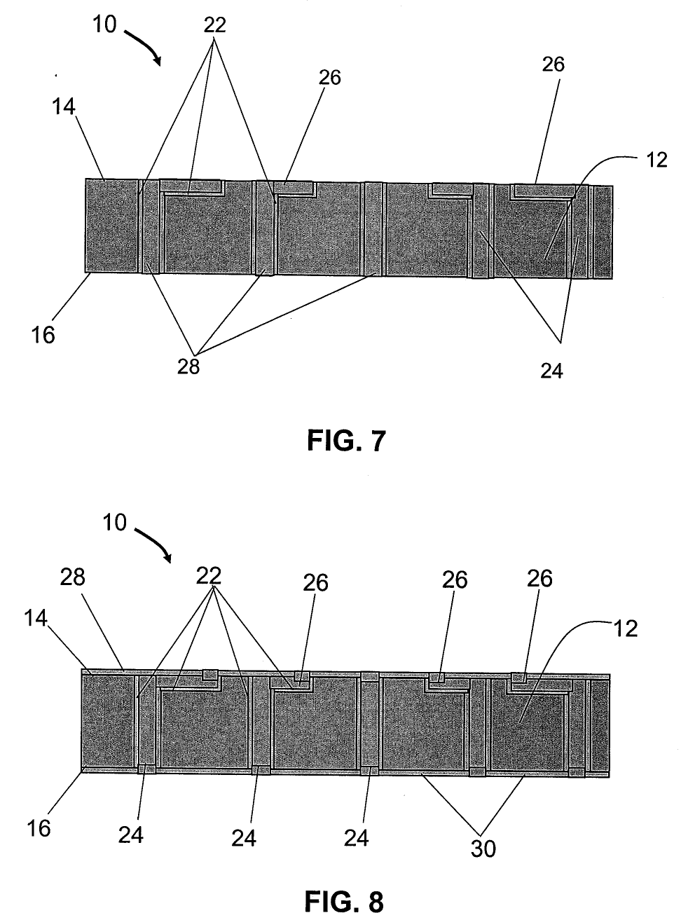

The first and second trenches 18, 20 may be lined with dielectric material 22 as shown in FIG. 6 and then filled with a conductive material 28 as shown in FIG. 7. The conductive material 28 may be doped or undoped polysilicon (poly) or a metal. Preferably, the trenches 18, 20 are completely filled using a highly doped poly so that the resulting path defined by the fill material 28 is highly conductive. The poly fill material 28 may be n-doped or p-doped. Further, the poly fill material 28 may be deposited as in-situ doped poly or may be deposited as undoped poly and subsequently diffused with Phosphorous or Boron to achieve a high conductivity. The filled trenches 18, 20 form the conductive vias 24, 26, respectively. After the refill, the partially formed adapter 10 is planarized or polished using CMP or other techniques known in the art.

FIG. 8 shows that the first and second dielectric layers 28, 30 are then formed or deposited on the first and second surfaces 14, 16, respectively. The dielectric layers 28, 30 may be formed by low pressure (LP) chemical vapor deposition (CVD) Tetraethylorthosilicate (TEOS), a spun-on-glass (SOG) deposition or other techniques known in the art. The partially formed adapter 10 may then be masked and etched again to reveal portions of the first and second conductive vias 24, 26. Finally, as shown in FIG. 1, the electrical contacts 32, 34 are formed on the first and second conductive vias 24, 26.

From the foregoing, it can be seen that embodiments of the present invention are directed to a varying pitch adapter and a method of forming a varying pitch adapter. It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

We claim:

1. A method for forming a varying pitch adapter, the method comprising:
providing a substrate having a first main surface and a second main surface opposite the first main surface;
forming a plurality of first trenches through the substrate from the first main surface to the second main surface;
forming at least one second trench adjacent to one of the plurality of first trenches on at least one of the first main surface and the second main surface; and
at least partially filling the first trenches and the at least one second trench with a conductive material.

2. The method according to claim 1, wherein the plurality of first trenches are formed by Reactive Ion Etching (RIE).

3. The method according to claim 2, wherein the at least one second trench is formed by RIE.

4. The method according to claim 3, further comprising:
prior to forming the plurality of first trenches, forming a first photomask over at least a portion of the first main surface of the substrate; and
after forming the plurality of first trenches, removing the first photomask from the first main surface of the substrate.

5. The method according to claim 4, further comprising:
prior to forming the least one second trench, forming a second photomask over at least a portion of one of the first main surface and the second main surface of the substrate; and
after forming the least one second trench, removing the second photomask from the first main surface or the second main surface of the substrate.

6. A varying pitch adapter made by the method according to claim 5.

7. The method according to claim 1, further comprising:
forming a first dielectric layer on the first main surface of the substrate while keeping at least a portion of the partially filled trenches exposed; and
forming a second dielectric layer on the second main surface of the substrate while keeping at least a portion of the partially filled trenches exposed.

8. The method according to claim 7, further comprising:
forming a third dielectric layer on inner surfaces of the plurality of first trenches and the at least one second trench.

9. A varying pitch adapter made by the method according to claim 1.

10. The method according to claim 1, wherein the first and second trenches are formed in the substrate by one of laser drilling/etching, water jet drilling/etching, mechanical machining, mechanical etching, dry chemical etching and wet chemical etching.

11. The method according to claim 1, wherein the substrate is formed of one of silicon (Si), gallium arsenide (GaAs), germanium (Ge), aluminum, copper, sapphire, diamond, silicon carbide (SiC) and ceramic.

12. The method according to claim 1, wherein the substrate is formed of a semiconductor material.

13. A method for forming a varying pitch adapter for electronic components, the method comprising:
providing a semiconductor substrate having a first main surface and a second main surface opposite the first main surface;
forming a plurality of first trenches through the substrate from the first main surface to the second main surface by reactive ion etching (RIE);
forming a plurality of second trenches in one of the first and the second main surfaces, each of the plurality of second trenches being disposed adjacent to a respective one of the plurality of first trenches;
lining walls of the plurality of first trenches and walls of the plurality of second trenches with a dielectric material;
filling the plurality of first trenches and the plurality of second trenches with a conductive material in order to create a plurality of conductive vias through the semiconductor substrate;
forming a first dielectric layer on the first main surface of the semiconductor substrate with the dielectric material;
forming a second dielectric layer on the second main surface of the semiconductor substrate with the dielectric material;
exposing a portion of each of the plurality of conductive vias on the first main surface of the semiconductor substrate; and
exposing a portion of each of the plurality of conductive vias on the second main surface of the semiconductor substrate.

14. A varying pitch adapter made by the method according to claim 13.
